(19) United States
(12) Patent Application Publication
(10) Pub. No.: US 2018/0061807 A1
(43) Pub. Date: Mar. 1, 2018

(54) SEMICONDUCTOR PACKAGE AND METHOD OF MANUFACTURING THE SAME

(71) Applicant: SAMSUNG ELECTRO-MECHANICS CO., LTD., Suwon-si (KR)

(72) Inventor: Young Pyo LEE, Suwon-si (KR)

(73) Assignee: SAMSUNG ELECTRO-MECHANICS CO., LTD., Suwon-si (KR)

(21) Appl. No.: 15/453,387

(22) Filed: Mar. 8, 2017

(30) Foreign Application Priority Data
Aug. 26, 2016 (KR) 10-2016-0108941

(51) Int. Cl. H01L 25/065; H01L 23/538; H01L 23/31; H01L 21/56; H01L 23/00; H01L 21/3105; H01L 23/367; H01L 25/00

(52) U.S. Cl. CPC H01L 25/0652; H01L 24/17; H01L 23/3128; H01L 21/565; H01L 24/81; H01L 21/31053; H01L 23/3675; H01L 25/50; H01L 23/5385; H01L 2225/06517; H01L 2225/06572; H01L 2225/06589; H01L 2924/19105; H01L 2224/16225; H01L 2225/06586; H01L 2225/06548; H01L 23/5386

(57) ABSTRACT

A semiconductor package includes a first substrate, a second substrate, a sealing member, a first conductive member, and a second conductive member. Electronic components are disposed on both surfaces of the first substrate. The second substrate is disposed on a surface of the first substrate. The sealing member is disposed on both surfaces of the first substrate to cover the electronic components. The first conductive member is disposed on the second substrate. The second conductive member is disposed on the sealing member connected to the first conductive member.

### CROSS-REFERENCE TO RELATED APPLICATION

This application claims the benefit under 35 USC 119(a) of Korean Patent Application No. 10-2016-0108941, filed on Aug. 26, 2016 in the Korean Intellectual Property Office, the entire disclosure of which is incorporated herein by reference for all purposes.

### BACKGROUND

1. Field

The following description relates to a semiconductor package configured to dissipating heat from an electronic component to an outside, and a method of manufacturing the same.

2. Description of Related Art

As miniaturization and thinning of a semiconductor package have been demanded, a semiconductor package includes a large number of electronic components integrally formed therein. However, because a plurality of electronic components are integrated on a single substrate in such a semiconductor package as that described above, at least one of the electronic components overheats and malfunctions.

Therefore, it is necessary to develop a semiconductor package effectively dissipating heat generated by the electronic components in the semiconductor package.

### SUMMARY

This Summary is provided to introduce a selection of concepts in a simplified form that are further described in the Detailed Description below. This Summary is not intended to identify key features or essential features of the claimed subject matter, nor is it intended to be used as an aid in determining the scope of the claimed subject matter.

Examples describe a semiconductor package configured to effectively dissipate heat generated by an electronic component and a method of manufacturing the same.

In accordance with an embodiment, there is provided a semiconductor package, including: a first substrate, wherein electronic components are disposed on both surfaces of the first substrate; a second substrate disposed on a surface of the first substrate; a sealing member disposed on both surfaces of the first substrate to cover the electronic components; a first conductive member disposed on the second substrate; and a second conductive member disposed on the sealing member connected to the first conductive member.

The second conductive member may be disposed on a surface of the sealing member.

The second substrate may include a square shape of which a center may be open.

The first substrate may include a first connection pad connected to the first conductive member.

The second substrate may include a second connection pad connected to the first conductive member.

The first conductive member may be disposed on a side surface of the second substrate.

A height from one surface of the first substrate to an outer surface of the second conductive member may be greater than a height from the one surface of the first substrate to an outer surface of the second substrate.

The second conductive member may include a grounding member connected to a grounding pad of the first substrate, and a heat radiating member connected to a connection pad of the first substrate.

In accordance with another embodiment, there is provided a method of manufacturing a semiconductor package, including: disposing an electronic component and a second substrate on one surface of a first substrate; forming a first conductive member on the second substrate; forming a sealing member on the first substrate; polishing the sealing member; and forming a second conductive member on the sealing member.

The polishing the sealing member may be performed to a same height as the second substrate.

In accordance with an embodiment, there is provided a semiconductor package, including: a first substrate comprising electronic components formed on both surfaces of the first substrate, wherein the electronic components are interconnected through a printed circuit of the first substrate; a second substrate disposed on one surface of the first substrate; a first sealing member formed on another surface of the first substrate; a second sealing member formed on the one surface of the first substrate, wherein the first and the second sealing members are configured to cover the electronic components; a first conductive member configured to define an internal region of the second substrate surrounding the electronic components formed within the second sealing member; and a second conductive member disposed on an outer surface of the second sealing member and covering the internal region, wherein the first and the second conductive members are connected to the printed circuit.

A first height, from the one surface of the first substrate to an outer surface of the second conductive member, may be greater than a second height, from the one surface of the first substrate to an outer surface of the second substrate.

The first conductive member may be disposed on two side surfaces of the second substrate.

The semiconductor package may also include: a first connection pad connected to the first conductive member and disposed in the first substrate.

The semiconductor package may also include: a second connection pad connected to the first conductive member and disposed in the second substrate.

The second conductive member may be formed in predetermined portions of the second sealing member.

The first conductive member may be formed and disposed in two side surfaces, a first side surface and a second side surface, of the second substrate, divided by the second sealing member, and wherein the first side surface and the second side surface are at opposite sides of the second sealing member.

The second conductive member may include a heat radiating member connected to the first conductive member, which may be connected to the first connection pad of the first substrate, and a grounding member connected to a second conductive member, which may be connected to the grounding pad of the first substrate.

The heat radiating member may include a larger area than or substantially same area as the grounding member.

The first conductive member may be connected to a first connection pad and a grounding pad of the first substrate.

Other features and aspects will be apparent from the following detailed description, the drawings, and the claims.

### BRIEF DESCRIPTION OF THE DRAWINGS

FIG. 1 is a cross-sectional view illustrating a semiconductor, package according to an example.

FIG. 2 is a bottom view of the semiconductor package of the example of FIG. 1.

FIG. 3 is a cross-sectional view illustrating a semiconductor, package according to another example.

FIG. 4 is a bottom view of the semiconductor package of the example of FIG. 3.

FIG. 5 is a cross-sectional view illustrating a semiconductor package, according to a different example.

FIG. 6 is a bottom view of the semiconductor package of an example of FIG. 5.

FIG. 7 is a cross-sectional view illustrating a semiconductor package, according to a further example.

FIG. 8 is a bottom view of the semiconductor package of the example of FIG. 7.

FIG. 9 is a process view illustrating a method to manufacture a semiconductor package, according to an example.

FIG. 10 is a process view illustrating a method to manufacture a semiconductor package, according to another example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

It will be understood that when an element or layer is referred to as being “on” or “connected to” another element or layer, it can be directly on or connected to the other element or layer or through intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. These terms do not necessarily imply a specific order or arrangement of the elements, components, regions, layers and/or sections. Thus, a first element, component, region, layer or section discussed below could be termed a second element, component, region, layer or section without departing from the teachings description of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Subsequently, examples are described in further detail with reference to the accompanying drawings.

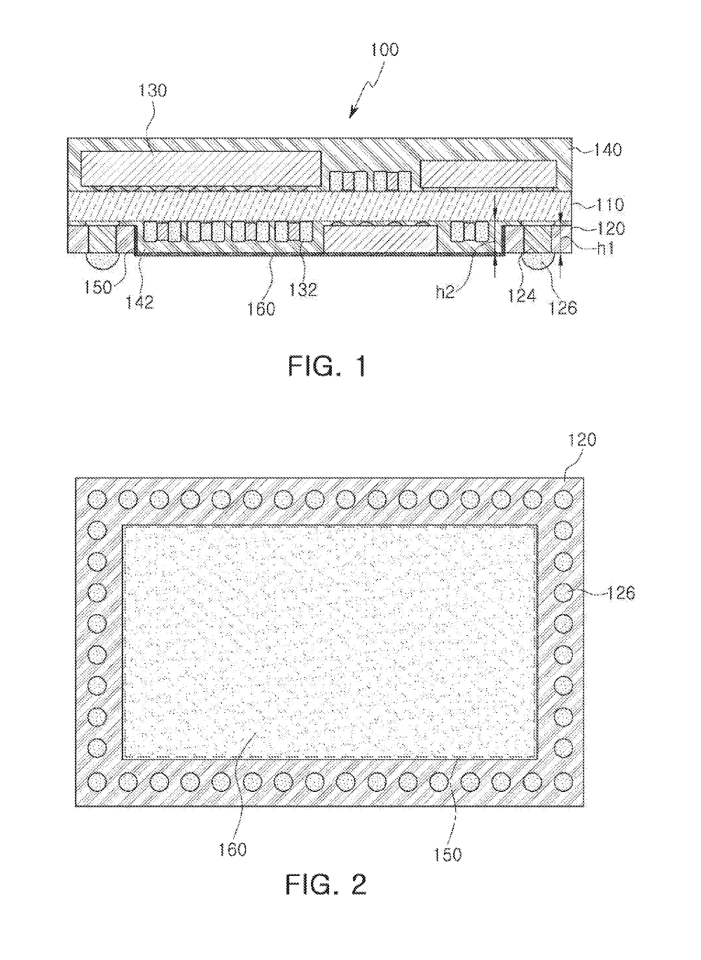

With reference to FIG. 1, a semiconductor package, according to an example, will be described.

A semiconductor package 100 includes a first substrate 110, a second substrate 120, electronic components 130 and 132, sealing members 140 and 142, and conductive members 150 and 160. In addition, the semiconductor package 100 may further include additional components.

The first and the second substrates 110 and 120 are formed of an insulating material. For example, the substrates 110 and 120 may be formed of a material such as resin, ceramic, or polyurethane. In addition, each of the first substrate 110 and the second substrate 120 includes a printed circuit (not shown), forming one or more electrical circuits. For example, a first printed circuit is formed on an upper surface of the first substrate 110, and a second printed circuit is formed on a lower surface of the first substrate 110. In one configuration, the first printed circuit and the second printed circuit are interconnected. For example, the first printed circuit and the second printed circuit are connected by a via electrode passing through the first substrate 110. However, the first printed circuit and the second printed circuit may not be connected to each other.

In one embodiment, the first substrate 110 has a substantially rectangular plate form, and the second substrate 120 has a rectangular shape of which a middle portion is open.

The second substrate 120 includes a via electrode 124 and a solder ball 126. The via electrode 124 is formed to be long in a height direction of the second substrate 120. The via electrode 124 formed as described above may be connected to a printed circuit or a connection pad of the first substrate 110. The solder ball 126 is disposed on a lower surface of the second substrate 120. For example, the solder ball 126 is disposed on a lower surface of the second substrate 120 to be connected to the via electrode 124. The solder ball 126 disposed as described above is connected to the electronic components 130 and 132 of the semiconductor package 100 through the second substrate 120, to enable transmission of a signal from the electronic components 130 and 132 to an external receiver or an external electronic device or to receive an external signal and transfer the external signal to the electronic components 130 and 132.

The electronic components 130 and 132 are disposed on the first substrate 110. For example, one or more electronic components 130 and 132 are disposed on an upper surface and a lower surface of the first substrate 110. The electronic components 130 and 132 are electrically interconnected. For example, the electronic components 130 and 132 are interconnected through a printed circuit of the first substrate 110. However, not all the electronic components 130 and 132 need to be connected by a printed circuit. For example, an electronic component 130 is connected through a printed circuit of the first substrate 110, but is not electrically connected to the other electronic component 132.

The sealing members 140 and 142 are formed on the first substrate 110. In one configuration, the sealing members 140 and 142 are formed on both surfaces, an upper surface and a lower surface, of the first substrate 110. The sealing members 140 and 142 are formed to have a predetermined height. For example, the sealing members 140 and 142 are formed to have a sufficient height to entirely cover the electronic components 130 and 132. The sealing members 140 and 142 are formed of an insulating material. For example, the sealing members 140 and 142 are formed of a resin material. However, a material of the sealing members 140 and 142 is not limited to a resin. For example, a material of the sealing members 140 and 142 may be a mixed material including a metal powder. In this case, through the sealing members 140 and 142, a harmful electromagnetic wave may be shielded.

The sealing members 140 and 142 includes a first sealing member 140 and a second sealing member 142. The first sealing member 140 is disposed above the first substrate 110, and the second sealing member 142 is disposed below the first substrate 110. The sealing members 140 and 142 disposed as described above protect the electronic components 130 and 132 from external impacts.

The conductive members 150 and 160 are configured to dissipate heat generated by the electronic components 130 and 132. For example, the conductive members 150 and 160 may be connected to a printed circuit of the substrates 110 and 120, to absorb heat generated by the electronic components 130 and 132 to dissipate the heat to an exterior of the semiconductor package 100.

The conductive members 150 and 160 include a first conductive member 150 and a second conductive member 160. The first conductive member 150 is disposed on the second substrate 120. For example, the first conductive member 150 is disposed on four side surfaces of the second substrate 120. For example, the first conductive member 150 defines or surrounds an internal portion or an internal region (as shown in FIG. 2) of the second substrate 120. In one illustrative example, the internal portion or the internal region is defined as a portion or region of the second sealing member 142 including all of the electronic components therein. The second conductive member 160 is disposed on the second sealing member 142. For example, the second conductive member 160 is disposed on an outer surface of the second sealing member 142.

The second conductive member 160 covers and is located near or on an outer surface of the semiconductor package 100. The second conductive member 160 is positioned or disposed on the outer surface of the second sealing member 142. For example, a height h2, from a lower surface of the first substrate 110 to an outer surface of the second conductive member 160, is greater than a height h1, from a lower surface of the first substrate 110 to an outer surface of the second substrate 120.

With reference to FIG. 2, a shape of a bottom surface of a semiconductor package will be described.

The semiconductor package 100 has a shape of a bottom surface as described in FIG. 2. For example, the second substrate 120 and the solder ball 126 may be disposed on an edge of the semiconductor package 100, and the second conductive member 160 may be disposed in a center of the semiconductor package 100.

The semiconductor package 100 formed as above transmits heat produced by the electronic components 130 and 132 through the second conductive member 160 disposed in a center of a lower portion thereof, to reduce an overheating phenomenon of the electronic components 130 and 132.

Next, a semiconductor package according to another example will be described. For reference, in the following description, the same components as those in the above-described example will use the same reference numerals as those in the above-described example, and a detailed description of these components will be omitted.

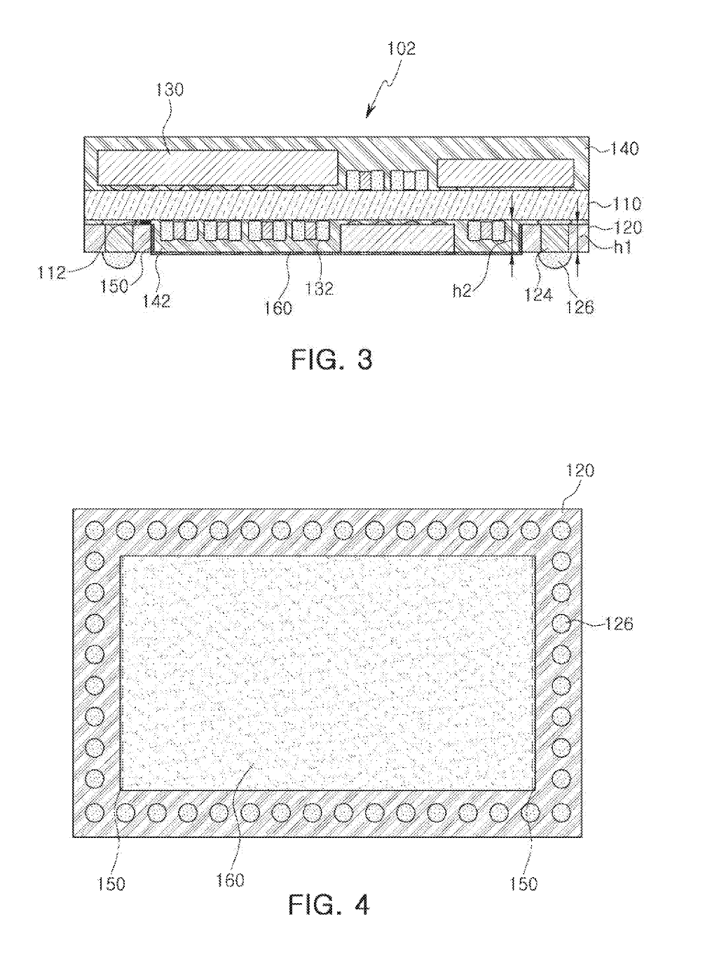

First, with reference to FIGS. 3 and 4, a semiconductor package, according to another example, will be described.

A semiconductor package 102, according to an example, is different from the above-described example in a connection structure of a conductive member. For example, a first conductive member 150 may be configured to be directly connected to a first substrate 110. A first connection pad 112 configured to be connected to the first conductive member 150 is disposed in the first substrate 110.

In addition, the semiconductor package 102, according to an example, is different from the above-described example due to a configuration of the first conductive member 150. For example, the first conductive member 150 is disposed on two side surfaces of a second substrate 120.

In the semiconductor package 102, the first conductive member 150 is directly connected to the first substrate 110 onto which the electronic components 130 and 132 are disposed, and thus the heat emitted from the electronic components 130 and 132 is quickly absorbed.

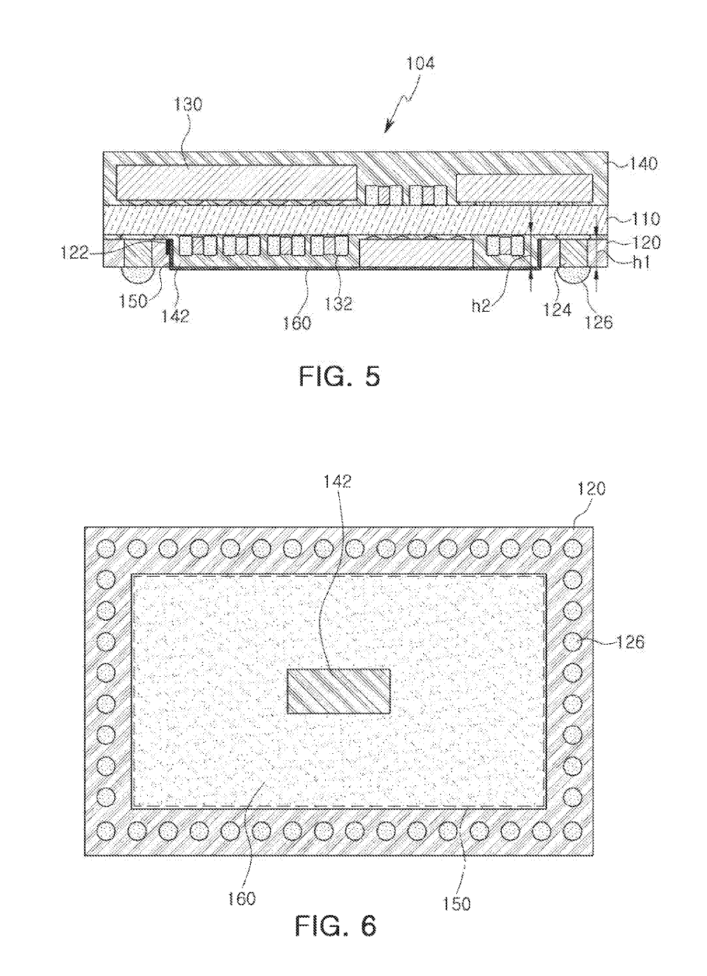

With reference to FIGS. 5 and 6, a semiconductor package, according to a different example, will be described.

A semiconductor package 104, according to an example, is different from the above-described examples in a connection structure of a conductive member. For example, a first conductive member 150 is configured to be directly connected to a second substrate 120. To this end, a second connection pad 122, configured to be connected to the first conductive member 150, is disposed in the second substrate 120.

In addition, the semiconductor package 104 has a different configuration from the one previously described for a second conductive member 160. For example, the second conductive member 160 is formed in particular regions of a second sealing member 142, as illustrated in FIG. 6.

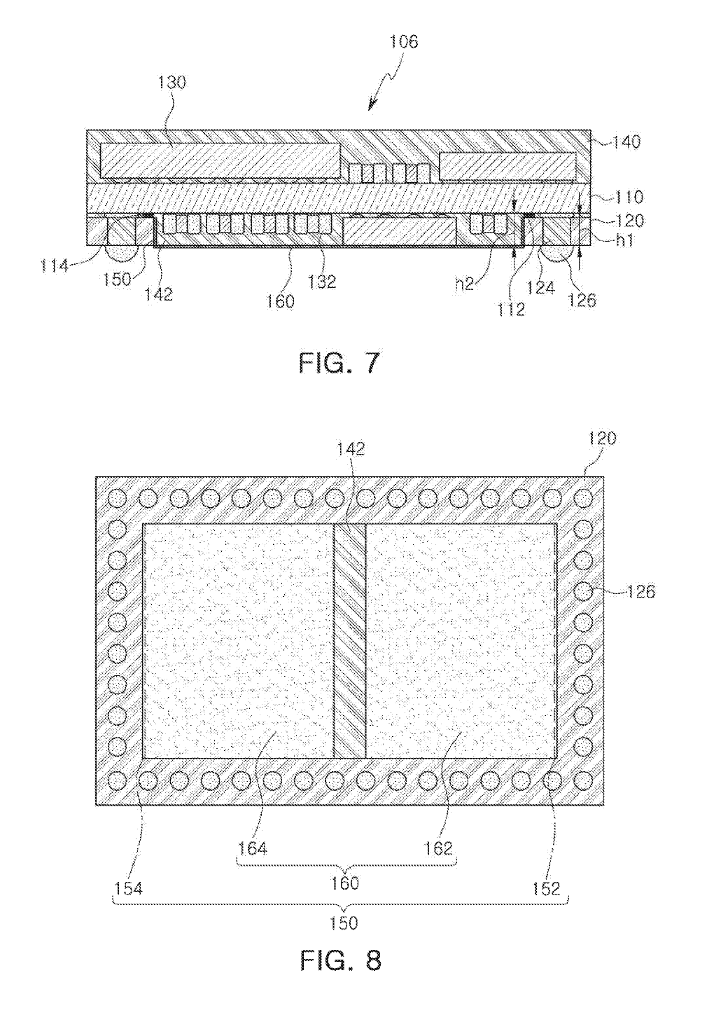

With reference to FIGS. 7 and 8, a semiconductor package, according to a different example, will be described.

A semiconductor package 106, according to an example, is different from the above-described examples in a connection structure of a conductive member. For example, a first conductive member 150 is connected to each of a first connection pad 112 and a grounding pad 114 of a first substrate 110.

In addition, the semiconductor package 106, according to an example, is different from the above-described example due to a different configuration of the first conductive member 150. For example, the first conductive member 150 is formed and disposed in two side surfaces, a first side surface and a second side surface, of the second substrate 120, divided by the second sealing member 142. In one configuration, the first side surface and the second side surface, in which the first conductive member 150 is formed, are surfaces at opposite sides of the second sealing member 142.

In addition, the semiconductor package 106, according to an example, is different from the above-described example based on the configuration of a second conductive member 160. For example, the second conductive member 160 includes a heat radiating member 162 and a grounding member 164, as illustrated in FIG. 8. The heat radiating member 162 is connected to a first conductive member 152, which is connected to the first connection pad 112 of the first substrate 110. The grounding member 164 is connected to a second conductive member 154, which is connected to the grounding pad 114 of the first substrate 110.

In one configuration, the heat radiating member 162 and the grounding member 164 are not in contact with each other. The heat radiating member 162 is formed to have a larger area compared to the grounding member 164. However, an area of the heat radiating member 162 is not necessarily larger than an area of the grounding member 164. For example, an area of the heat radiating member 162 is substantially the same as an area of the grounding member 164, as illustrated in FIG. 8.

The semiconductor package 106 configured as above performs a heat radiating function or a heat dissipating function and a grounding function through the conductive members 150 and 160.

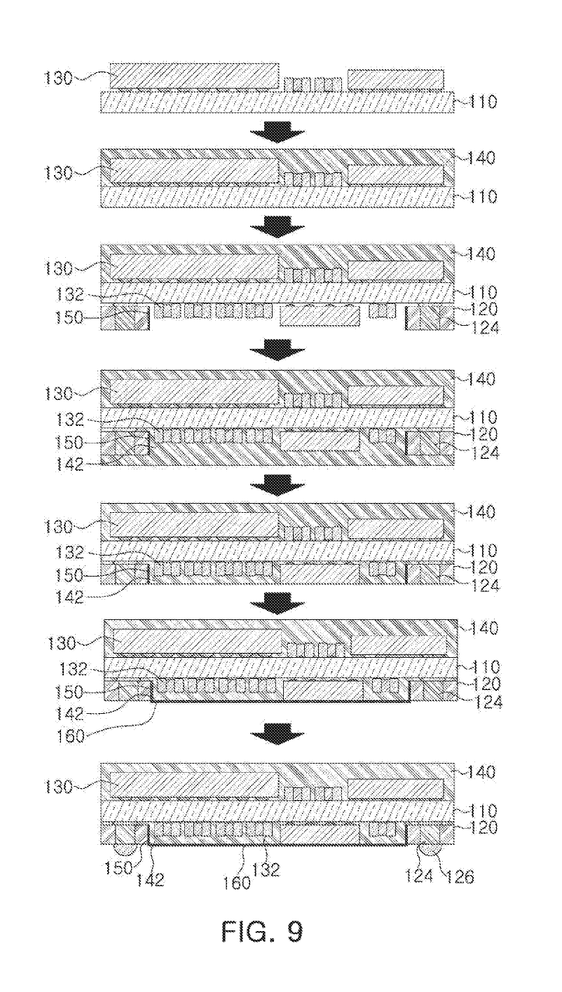

Next, with reference to FIG. 9, a method to manufacture a semiconductor package, according to an example, will be described. For reference, in the description of the method to manufacture a semiconductor package, the same components as those of the semiconductor package described above will use the same reference numerals as those of the semiconductor package described above, and a detailed description of these components will be omitted.

The method of manufacturing a semiconductor package, according to an example, includes disposing a first electronic component, forming a first sealing member, disposing a second substrate and a second electronic component, forming a first conductive member, forming a second sealing member, polishing, forming a second conductive member, and forming a solder ball.
1) Disposing or placing a first electronic component

Disposing or placing a first electronic component includes a series of processes for disposing, positioning, or placing and connecting a plurality of first electronic components 130 in a first substrate 110. For example, the disposing or placing of a first electronic component includes a reflow process of heating the first substrate 110, in which the first electronic component 130 is disposed or placed, to electrically connect the first substrate 110 to the first electronic component 130.
2) Forming a first sealing member

Forming a first sealing member includes a series of processes to form a first sealing member 140 in an upper surface of the first substrate 110. The first sealing member 140 is formed to have a shape that completely accommodates the first electronic component 130. In one configuration, the forming a first sealing member is separated into two or more processes, and thus the first sealing member 140 is formed as the two or more processes are completed.
3) Disposing or placing a second substrate and a second electronic component

Disposing or placing a second substrate and a second electronic component includes a series of processes to dispose a second substrate 120 and a second electronic component 132 on a lower surface of the first substrate 110. Disposing or placing the second substrate 120 and disposing the second electronic component 132 are performed sequentially or may be performed simultaneously.
4) Forming a first conductive member

Forming a first conductive member includes a series of processes to form a first conductive member 150 on the second substrate 120. For example, the forming a first conductive member includes plating a metal material on a side surface of the second substrate 120 to form the first conductive member 150.
5) Forming a second sealing member

Forming a second sealing member includes a series of processes to form a second sealing member 142 on a lower surface of the first substrate 110. The second sealing member 142 is formed in a process that is the same as or similar to that of the first sealing member 140. In the forming of the second sealing member 142, the second sealing member 142 is formed to cover a lower surface of the second substrate 120. For example, during the formation of a second sealing member, the second sealing member 142 is formed to have a shape sufficient to fully cover lower surfaces of the second electronic component 132 and the second substrate 120.
6) Polishing

Polishing includes a series of processes to polish the second sealing member 142. For example, the polishing includes a process to measure a height of the second sealing member 142, to determine a polishing depth of the second sealing member 142.

Polishing the second sealing member 142 is performed until a lower surface of the second substrate 120 is exposed. In a configuration, the polishing includes a process to polish portions of the second sealing member 142 and the second substrate 120.
7) Forming a second conductive member

Forming a second conductive member includes a series of processes to form a second conductive member 160 in the second sealing member 142. For example, the formation of the second conductive member 142 includes a process of sputtering a metal material onto a surface of the second sealing member 142 to form the second conductive member 160. However, a method to form the second conductive member 160 is not limited to sputtering. Other deposition processes may be used to form the second conductive member 160.
8) Forming a solder ball

Forming a solder ball includes a series of processes to form a solder ball 126 on the second substrate 120. When the forming a solder ball is completed, a semiconductor package, according to an example, is completed.

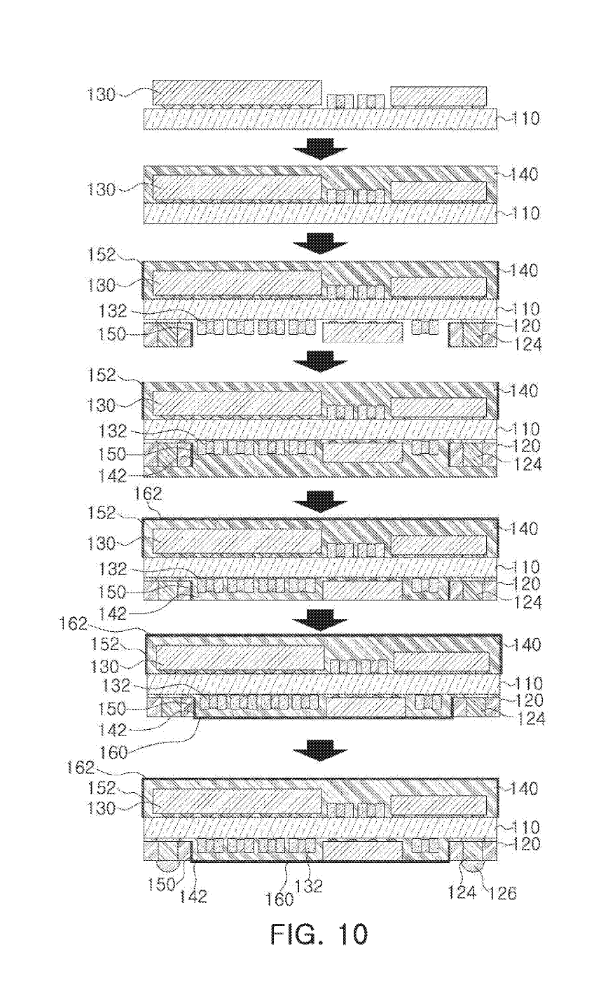

Next, a method to manufacture a semiconductor package according to another example will be described, with reference to FIG. 10.

A method to manufacture a semiconductor package, according to an example, is different from the above-described example in the forming a conductive member. For example, a method of manufacturing a semiconductor package also includes forming a first conductive member on a side surface of a second substrate 120 and a side surface of a first sealing member 140, and forming a second conductive member on an outer surface of the first sealing member 140 and an outer surface of a second sealing member 142.

In the method to manufacture a semiconductor package, conductive members are formed on surfaces of sealing members 140 and 142. As a result, a heat release effect through a conductive member may be further improved.

As set forth above, according to the various examples described, a malfunction caused by heating of a semiconductor package, and the like, may be significantly reduced.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package, comprising:
a first substrate, wherein electronic components are disposed on both surfaces of the first substrate;
a second substrate disposed on a surface of the first substrate;
a sealing member disposed on both surfaces of the first substrate to cover the electronic components;
a first conductive member disposed on the second substrate; and
a second conductive member disposed on the sealing member connected to the first conductive member.

2. The semiconductor package of claim 1, wherein the second conductive member is disposed on a surface of the sealing member.

3. The semiconductor package of claim 1, wherein the second substrate comprises a square shape of which a center is open.

4. The semiconductor package of claim 1, wherein the first substrate comprises a first connection pad connected to the first conductive member.

5. The semiconductor package of claim 1, wherein the second substrate comprises a second connection pad connected to the first conductive member.

6. The semiconductor package of claim 1, wherein the first conductive member is disposed on a side surface of the second substrate.

7. The semiconductor package of claim 1, wherein a height from one surface of the first substrate to an outer surface of the second conductive member is greater than a height from the one surface of the first substrate to an outer surface of the second substrate.

8. The semiconductor package of claim 1, wherein the second conductive member comprises a grounding member connected to a grounding pad of the first substrate, and a heat radiating member connected to a connection pad of the first substrate.

9. A method of manufacturing a semiconductor package, comprising:
disposing an electronic component and a second substrate on one surface of a first substrate;
forming a first conductive member on the second substrate;
forming a sealing member on the first substrate;
polishing the sealing member; and
forming a second conductive member on the sealing member.

10. The method of claim 9, wherein the polishing the sealing member is performed to a same height as the second substrate.

11. A semiconductor package, comprising:
a first substrate comprising electronic components formed on both surfaces of the first substrate, wherein the electronic components are interconnected through a printed circuit of the first substrate;
a second substrate disposed on one surface of the first substrate;
a first sealing member formed on another surface of the first substrate;
a second sealing member formed on the one surface of the first substrate, wherein the first and the second sealing members are configured to cover the electronic components;
a first conductive member configured to define an internal region of the second substrate surrounding the electronic components formed within the second sealing member; and
a second conductive member disposed on an outer surface of the second sealing member and covering the internal region, wherein the first and the second conductive members are connected to the printed circuit.

12. The semiconductor package of claim 11, wherein a first height, from the one surface of the first substrate to an outer surface of the second conductive member, is greater than a second height, from the one surface of the first substrate to an outer surface of the second substrate.

13. The semiconductor package of claim 11, wherein the first conductive member is disposed on two side surfaces of the second substrate.

14. The semiconductor package of claim 11, further comprising:
a first connection pad connected to the first conductive member and disposed in the first substrate.

15. The semiconductor package of claim 11, further comprising:
a second connection pad connected to the first conductive member and disposed in the second substrate.

16. The semiconductor package of claim 11, wherein the second conductive member is formed in predetermined portions of the second sealing member.

17. The semiconductor package of claim 11, wherein the first conductive member is formed and disposed in two side surfaces, a first side surface and a second side surface, of the second substrate, divided by the second sealing member, and wherein the first side surface and the second side surface are at opposite sides of the second sealing member.

18. The semiconductor package of claim 17, wherein the second conductive member comprises a heat radiating member connected to the first conductive member, which is connected to the first connection pad of the first substrate, and a grounding member connected to a second conductive member, which is connected to the grounding pad of the first substrate.

19. The semiconductor package of claim 17, wherein the heat radiating member comprises a larger area than or substantially same area as the grounding member.

20. The semiconductor package of claim 11, wherein the first conductive member is connected to a first connection pad and a grounding pad of the first substrate.
